(19) United States
(12) Patent Application Publication
(10) Pub. No.: US 2016/0105162 A1
(43) Pub. Date: Apr. 14, 2016

(54) METHODS AND APPARATUSES FOR ULTRA-LOW-POWER SYSTEM ON A CHIP (SoC) ACTIVITY WEARABLE DEVICES

(71) Applicants: Uzi Zangi, Hod-Hasharon (IL); Pavel Stessin, Rehovot (IL)

(72) Inventors: Uzi Zangi, Hod-Hasharon (IL); Pavel Stessin, Rehovot (IL)

(21) Appl. No.: 14/513,438

(22) Filed: Oct. 14, 2014

(51) Int. Cl. H03K 3/012

(52) U.S. Cl. CPC H03K 3/012

(57) ABSTRACT

An always-on chip incorporated inside an activity wearable device implemented as a System-On-a-Chip (SoC). The device includes a MCU and DSP and audio CODEC and a BLE circuit to detect user activation commands.

The user wakeup command is used to wake up the main application processor on the system.

Ultra low power consumption may be realized by implementing the CMOS die using sub-threshold technology and by using power and battery management algorithms based on the human activity detected by the integrated sensors.

### CLAIM OF PRIORITY

This application claims priority from U.S. Provisional patent application No. 61/902,460, entitled “METHODS AND APPARATUSES FOR ULTRA-LOW POWER SYSTEM ON A CHIP (SoC) ACTIVITY WEARABLE DEVICES”, filed on Nov. 11, 2013.

### FIELD

Embodiments of the invention relate generally to the field of activity wearable electronic devices, always-on chips, medical wearable devices, IoT (Internet of Things) devices and other battery powered devices and more specifically to ultra-low power consumption implementations of such devices.

### BACKGROUND

Many emerging applications require sensing and processing capabilities with ultra-low power consumption. This will allow them to be incorporated into devices that operate from a small non-rechargeable or rechargeable battery for very long periods without the need to frequently change the battery.

One such device example is an activity tracking wearable device that requires activity sensors like accelerometer and/or gyroscope for measuring the human movement and speed like walking, running, climbing up and down the stairs and similar activities.

Another such device example is an always-on chip that is incorporated into a cell phone or tablet system or a smart watch or a wearable device and monitors the different sensors inside the product which detect user activities, and/or device sensors, doing all the required data processing or pre-processing and waking up the main application processor only when relevant inputs are detected by the always-on chip (like either hand gestures, audio wakeup or wireless communication command) or when further processing on the preprocessed data is required. This functionality requires the lowest possible power consumption whilst performing continuous processing of inputs (such as measuring user gestures or analyzing microphone inputs) and outputs (such as audio playback) that does not require the activation of the main processor in the targeted device.

In other applications such as IOT or wearable devices, these devices also require a way to transmit the collected data back to a main device such as a “Smart Phone” with specific application for analysis of the sensor recordings; this data is transmitted using wireless protocols such as Bluetooth Smart (also known as Bluetooth Low Energy (BLE)).

Conventional implementations of always-on devices, sensors processors, wireless communication processors and input and output processors used in cell phones, tablets, smart watches, activity tracking wearable devices, IoT devices, medical wearable devices and other battery powered devices include systems comprised of single or multiple chips which operate at relatively high voltage (around 1-1.2 v) and because of this consume more energy. A major disadvantage of such implementations is that the device battery must be recharged frequently due to the high power consumption of these components. This disadvantage is one of the major limiting factors for today's cell phones, tablets, smart watches, IoT, activity tracking wearable devices, medical wearable devices and other battery powered devices which also limit the ability to add extra features to these devices.

### SUMMARY

For one embodiment of the invention, provide a System-On-A-Chip (SoC) implementation that integrates all the basic components which are needed for an always-on device, which includes a PMU (Power management unit), low power audio ADC and DAC, MCU, a wireless communication method (e.g., BlueTooth low energy (BLE)) and a DSP for the data processing, audio analysis and audio playback and/or data post processing, integrated memory and program flash.

Additionally, embodiments also include implementation of the CMOS die in a sub-threshold technology which operates the chip at a voltage of 0.45-0.55 v (which is below the threshold voltage of the transistor). This technology requires a unique and special low voltage standard cell and memory libraries that can give reasonable speed which can be used for low performance products like always-on chips, wearable and Internet-of-Things (IoT) devices.

Additionally, embodiments also include implementation of the required analog blocks such as audio ADC and DAC, level shifters and optionally wireless communication RF at low voltage of 0.55 v in order to reduce power consumption of these blocks to the ultra-low power target.

Additionally, embodiments also include implementation of power management unit (PMU) that includes a special DC2DC block which can operate between 0.45 v to 1.1 v and provide the SW different sensors from the die so the SW can optimize power using a special algorithm to estimate in which voltage to operate each unit inside the chip. The SW can also operate each component based on the known minimal frequency of different functions such as gesture control, audio wakeup etc. . . . and provide the required minimal voltage and sampling rate in order to minimize the energy consumption. These algorithms also take into account the wake-up and sleep time per component and make a smart decision when to wake-up the required unit or to send this unit to sleep. The algorithms, which may be run via software on the integrated MCU, provide power and voltage management control for all SoC units through specific hardware mechanisms. An exemplary power management algorithm is discussed below in reference to FIG. 2.

Additionally, embodiments may also include implementation of a special clock management unit (CMU). The CMU, controlled by the SW, which analyzes the required usage scenario per component, controls the frequency of each block in cooperation with the PMU which controls the voltage to each component.

For one embodiment, may also include implementation of one or more battery management algorithms. Such algorithms may be used to reduce the spikes in consumption from the external battery by operating each unit in a different time slot. Such algorithms may also use an internal or external large capacitor or super capacitor to compensate for the needed peak currents. An exemplary battery management system is discussed below in reference to FIG. 3.

Finally, the hardware implementation may also include a scheduler with specified intervals that wakes-up the MCU and the DSP during each interval. When each required function is complete, the scheduler will power-down these units until the next interval wherein the scheduler will wake up the MCU and DSP to make the next sample.

### BRIEF DESCRIPTION OF THE DRAWINGS

The invention may be understood by referring to the following description and accompanying drawings that are used to illustrate embodiments of the invention. In the drawings:

FIG. 1 illustrates a block diagram for an example of always-on chip implemented as a system on a chip in accordance with one embodiment of the invention;

FIG. 2 illustrates a power management method in accordance with one embodiment of the invention;

FIG. 3 illustrates a battery management system in accordance with one embodiment of the invention; and

### DETAILED DESCRIPTION

A method to design an ultra low power SoC for use inside cell phones, tablets, smart watches, activity tracking wearable devices, IoT devices, medical wearable devices and other battery powered devices based on sub-threshold technology and smart power and battery managements.

In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout the specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all features of a single disclosed embodiment. Thus, the claims following the Detailed Description are hereby expressly incorporated into this Detailed Description, with each claim standing on its own as a separate embodiment of this invention.

Embodiments of the invention are applicable in a variety of settings in which an always-on device, sensors processors, wireless communication processors and input and output processors are used inside cell phones, tablets, smart watches, activity tracking wearable devices, IoT devices, medical wearable devices and other battery powered devices.

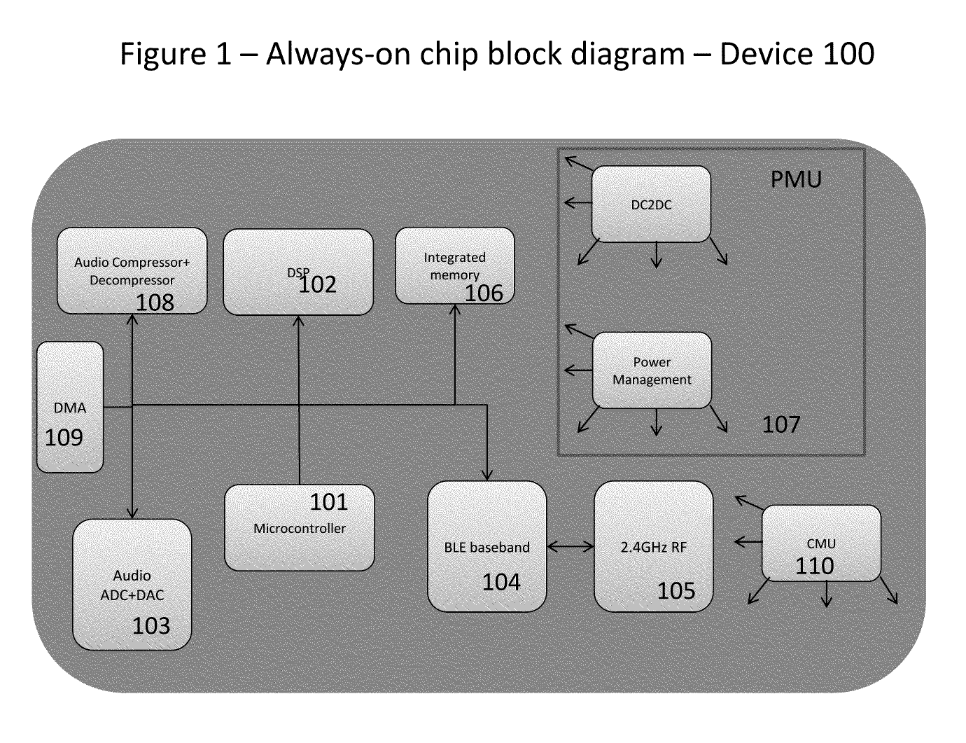

FIG. 1 illustrates a block diagram for an example always-on chip implemented as a system on a chip in accordance with one embodiment of the invention. As shown in FIG. 1, the device 100 includes an MCU 101 which is used for main algorithms implementations and general processing. The MCU 101 interfaces and controls all components at the SoC including a DSP 102 which is used for signal oriented data processing such as sensor analysis, audio analysis and other audio processing. Optional dedicated Audio Compressor and Decompressor includes a dedicated audio processing hardware for further power optimization over the more generic DSP and MCU processing implementations. The device 100 includes an audio ADC+DAC 103 for low power audio input (such as from microphones) and output (such as to speakers or headphones). The device 100 also includes a DMA to support direct access to memory between components without MCU or DSP intervention (such as audio playback through memory, Audio Decompressor, and Audio DAC). The device 100 also includes wireless data transmission functionality 104 and 105, shown for example as a BLE implementation, for transmitting data to an external device to be processed or displayed. The device 100 also includes power and battery management 107 to reduce energy consumption. The PMU 107 is also responsible to activate and deactivate portions of the device during specified intervals in order to reduce power consumption. The PMU 107 also includes a programmable DC2DC converter which connects directly to the battery voltage and can supply the different blocks voltage from 0.45 v-1.1 v. Device 100 also includes internal memory block and memory management unit 106 which has special memory which can store the sensors data for over a week of time and processing memory for all components Device 100 also includes a CMU 110 for clock generation per component depending on its processing requirements.

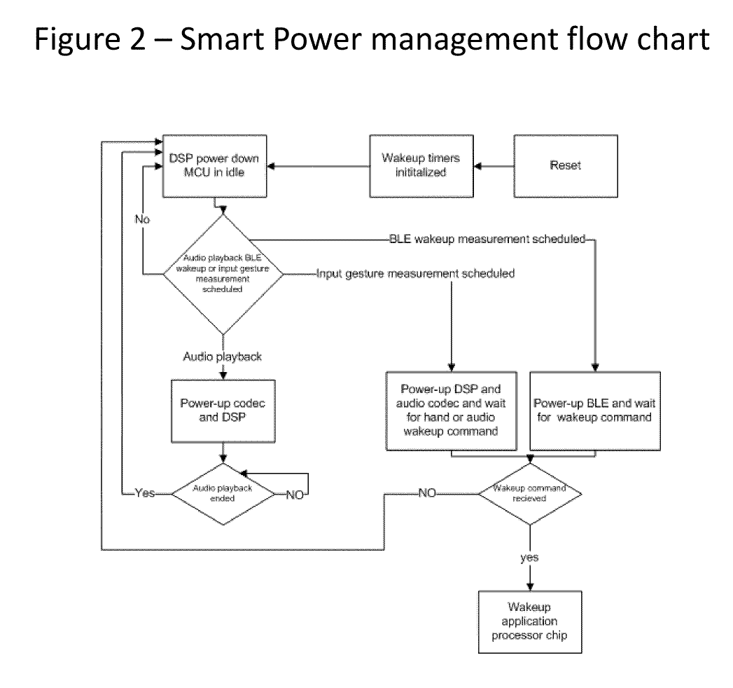

FIG. 2 illustrates a power management flow chart 200 in accordance with one embodiment of the invention. The process shown in FIG. 2 begins after reset (block 201) with programming the wakeup timers inside the PMU (block 202). The primary state of the system is with the DSP powered down and the MCU in idle state (block 203). According to the programmed timer wakeup schedule (block 204) the MCU and DSP are woken up either to perform audio playback (block 205), or to measure if a user wakeup command is detected via user activity (block 208) or BLE command (block 207). If an audio playback request was received then the audio codec and DSP are woken and audio playback is performed until audio playback is ended by the user (block 206). If a user wakeup (either via BLE, audio gesture or hand gesture) is detected (block 209) then the MCU wakes up the main application processor (block 210). If neither an audio playback command, or a wakeup command are received then the system returns to the idle state (block 203)

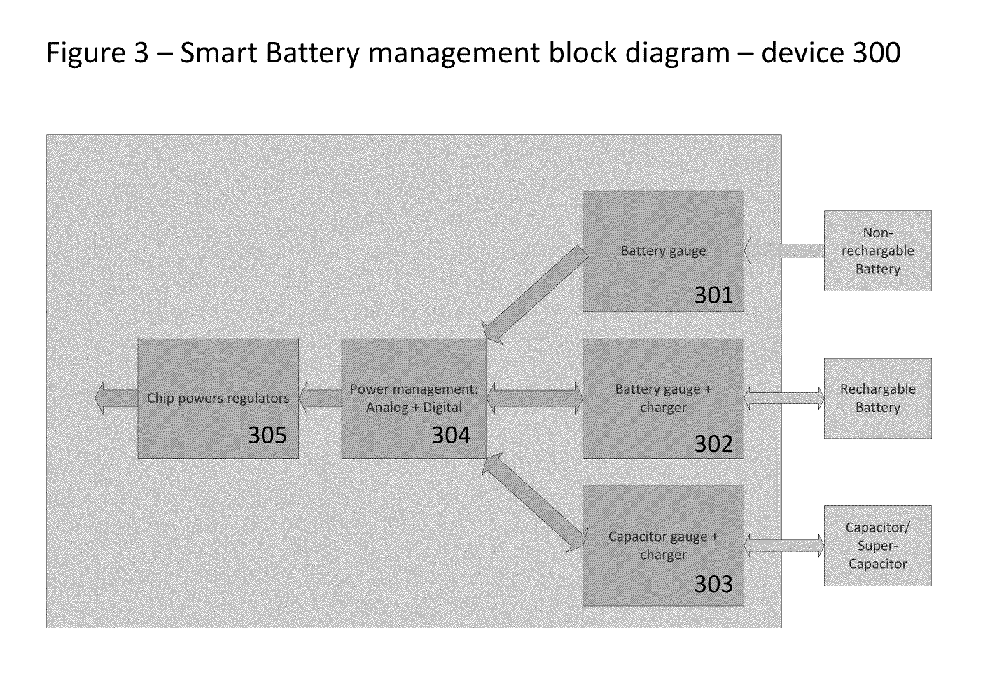

FIG. 3 illustrates a battery management system in accordance with one embodiment of the invention. The battery management system 300 shown in FIG. 3 includes gauges to monitor the non-rechargeable battery (block 301), the rechargeable battery (block 302), and the external capacitor (block 303) e.g., large/super capacitor. The gauge data is provided to the analog and digital power management (block 304) and the power regulators (block 305).

Embodiments of the invention have been described as including various operations. Many of the processes are described in their most basic form, but operations can be added to or deleted from any of the processes without departing from the scope of the invention.

The implementation may also include mechanisms for providing ultra-low power consumption from the device by using the following techniques: Sub-threshold implementation of the CMOS die design by using a special standard cell and memory libraries including special analog implementation at for example using 0.45-0.55 v operating voltage, smart power management that operate each unit based on its usage requirement rates and last smart battery management that unify the consumption current from the battery and eliminate un-needed spikes (which for example might degrade battery lifetime and increase power consumption).

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

What is claimed is:

1. A method to implement an always-on chip incorporated into a wearable device or Smart Phone or Smart Watch or IoT devices implemented as a system on a chip comprising one or more of the following blocks:
An audio ADC+DAC for audio output and input;
An audio Compressor+Decompressor for playback and recording of compressed audio;
A wireless data transmission functionality for data transmission and or low-power protocol processing; and
An integrated microcontroller unit and or integrated DSP unit to implement a data analysis mechanism, a data communication mechanism, audio input and output and wakeup gesture detection;
Finally included also a Power Management Unit (PMU), a Clock Management Unit (CMU) and a Battery Management Unit (BMU).

2. The device of claim 1 wherein the ASIC includes one or more logic cells or memory cells or analog blocks capable of operating at a sub-threshold operating voltage (for example 0.45 v or 0.55 v) to reduce the power consumption to an ultra-low target.

3. The device of claim 1 wherein the Power Management Unit uses knowledge of the lowest required frequency to process the required audio, sensors, gestures and wireless communication to activate a required logic at a rate based on the speed of the user activity.

4. The device of claim 1 wherein different mechanism at the device and or external host processor can be woken-up upon detection of required user activity.

5. The device of claim 1 wherein the Power Management Unit (PMU) comprises a scheduler mechanism that operates a portion of the device during each of multiple scheduling intervals in order to reduce spikes from the battery and a programmable DC 2 DC convertor which can change his output voltage dynamically from the Sub-Threshold voltage domain to the standard voltage (for example from 0.45 v to 1.1 v) by SW control depends on the required processing speed.

6. The device of claim 1 wherein the Clock Management Unit (CMU) can control frequency of each component separately per required usage operation.
